(19) United States
(12) Patent Application Publication
(10) Pub. No.: US 2012/0194933 A1
(43) Pub. Date: Aug. 2, 2012

(54) COLOR FILTER STRUCTURE AND MANUFACTURING METHOD THEREOF

(75) Inventor: CHUN-MING WU, Shenzhen (CN)

(73) Assignee: Shenzhen China Star Optoelectronics Technology Co. ,LTD., Shenzhen City (CN)

(21) Appl. No.: 13/220,686

(22) Filed: Aug. 30, 2011

(30) Foreign Application Priority Data
Jan. 28, 2011 (CN) 201110032967.4

(51) Int. Cl. G02B 5/22; G03F 1/00

(52) U.S. Cl. 359/891; 430/7

(57) ABSTRACT

The present invention discloses a color filter structure and a manufacturing method thereof. The color filter structure has a glass substrate, a black matrix layer, a color pixel layer, a plurality of spacers, a transparent conductive layer and a transparent planarized photo-resist layer. The present invention can simultaneously form the spacers by using the same color resist when forming the color pixel layer. Thus, the color filter structure of the present invention is relatively simple, and the manufacture cost thereof is relatively low, so as to save the manufacture cost of the color filter structure. In addition, the transparent planarized photo-resist layer can prevent the transparent conductive layer from generating short circuit problems during installation.

### FIELD OF THE INVENTION

The present invention relates to the technical field of liquid crystal display (LCD) panels, and more particularly to a color filter structure and a manufacturing method thereof.

### BACKGROUND OF THE INVENTION

A liquid crystal display (LCD) is a type of flat panel display (FPD), which shows images by the property of liquid crystal material. Comparing with other display devices, the liquid crystal display has advantages in lightweight, compactness, low driving voltage and low power consumption, and thus has already become the mainstream product in the whole consumer market.

In a traditional process of liquid crystal display (LCD) panels, it comprises a front-end array process, a mid-end cell process and a back-end modulation process, wherein the front-end array process is used to produce thin-film transistor (TFT) substrates and color filter (CF) substrates; the mid-end cell process is used to combine the TFT substrate with the CF substrate, then fill liquid crystal into a space therebetween, and cut to form panels with a suitable product size; and the back-end modulation process is used to execute an installation process of the combined panel, a backlight module, a panel driver circuit, an outer frame and etc.

The LCD can display color images based on the function generated by the color filter: when a backlight source of the LCD is controlled and adjusted by the liquid crystal material and a driver IC to provide a light source of gray scale, the light source of gray scale can pass through the color filter to for red, green and blue light due to three color resists coated on the color filter, and the red, green and blue light are finally mixed with each other into the color images. Therefore, the color filter is a key component of LCD, and the basic structure of the color filter is constructed by a glass substrate, a black matrix, a color pixel layer and an ITO (indium tin oxide) layer.

Referring now to FIGS. 1A to 1G, schematic views of a traditional manufacturing method of a color filter structure are illustrated.

Firstly, as shown in FIG. 1A, preparing a glass substrate 11 and forming a black matrix 12 on the glass substrate 11, wherein the black matrix 12 defines a plurality of blank spaces.

Then, as shown in FIG. 1B, forming first color resist units 13a in the corresponding blank spaces of the black matrix 12 on the glass substrate 11.

Then, as shown in FIG. 1C, forming second color resist units 13b in the corresponding blank spaces of the black matrix 12 on the glass substrate 11.

Then, as shown in FIG. 1D, forming third color resist units 13c in the corresponding blank spaces of the black matrix 12 on the glass substrate 11.

Each of the color resist units 13a, 13b and 13c has the same horizontal height, and individually disposed in the corresponding blank spaces of the black matrix 12. One of the first color resist units 13a, one of the second color resist units 13b and one of the third color resist units 13c form a set of pixel unit 130, and all of the pixel units 130 commonly form a color pixel layer 13.

Then, as shown in FIG. 1E, forming a transparent conductive layer 14 covered on the black matrix 12 and the color pixel layer 13.

Then, as shown in FIG. 1F, forming a photo-resist layer 15 on the transparent conductive layer 14.

Then, as shown in FIG. 1G, using a photo-mask (not-shown) to carry out processes of exposure and development for the photo-resist layer 15, so as to define a plurality of spacers 15a.

The foregoing steps can be used to prepare a traditional color filter structure 10, which comprises: a glass substrate 11, a black matrix 12, a color pixel layer 13, a transparent conductive layer 14 and a plurality of spacers 15a. The glass substrate 11 is used as a base material; the black matrix 12 is formed on the glass substrate 11, while the black matrix 12 has a plurality of blank spaces (un-labeled); The color pixel layer 13 comprises a plurality of first color resist units 13a, a plurality of second color resist units 13b and a plurality of third color resist units 13c, wherein the first, second and third color resist units 13a, 13b and 13c are formed in the corresponding blank spaces of the black matrix 12, respectively. Material of the color resist units 13a, 13b and 13c is preferably red (R) color resist, green (G) color resist and blue (B) color resist.

Furthermore, the transparent conductive layer 14 is covered on the black matrix 12 and the color pixel layer 13; the spacers 15a are formed on the transparent conductive layer 14, wherein each of the spacers 15a has a height greater than the height of each of the color resist units 13a, 13b and 13c. When the color filter structure 10 is further installed with a TFT substrate, the spacers 15a keeps a gap distance between the color filter structure 10 and the TFT substrate for evenly filling the liquid crystal material into the gap.

However, in the traditional manufacturing method of the color filter structure 10, the final step must use the processes of exposure and development to form the spacers 15a, wherein it needs to execute steps of forming the photo-mask 15, forming the photo-mask, exposure and development. As a result, the manufacture process of the spacers 15a is relatively complicated and the manufacture cost thereof is relatively high, resulting in increasing the manufacture cost of the color filter structure 10.

As a result, it is necessary to provide a color filter structure and a manufacturing method thereof to solve the problems existing in the conventional technologies, as described above.

### SUMMARY OF THE INVENTION

A primary object of the present invention is to provide a color filter structure and a manufacturing method thereof, which can omit a step of forming a photo-resist layer and locally exposing the photo-resist layer to form spacers.

To achieve the above object, the present invention provides a manufacturing method of a color filter structure, which comprises the following steps of:

preparing a glass substrate and forming a black matrix layer on the glass substrate, wherein the black matrix layer defines a plurality of blank spaces;

forming a plurality of first color resist units, second color resist units and third color resist units in the corresponding blank spaces of the black matrix layer, respectively, wherein the first, second and third color resist units commonly define a color pixel layer;

using the same color resist material of the first color resist units to form first spacer portions on the black matrix layer in the same process of forming the first color resist units;

using the same color resist material of the second color resist units to form second spacer portions on the first spacer portions in the same process of forming the second color resist units;

using the same color resist material of the third color resist units to form third spacer portions on the second spacer portions in the same process of forming the third color resist units, wherein each of the first spacer portions, the second spacer portions and the third spacer portions are stacked to form a spacer;

forming a transparent conductive layer covered on the black matrix layer, the color pixel layer and the spacers; and

forming a transparent planarized photo-resist layer covered on the transparent conductive layer.

In one embodiment of the present invention, in the step of forming the first color resist units in the corresponding blank spaces of the black matrix layer and using the same color resist material of the first color resist units to form the first spacer portions on the black matrix layer in the same process of forming the first color resist units, comprising: forming a first color resist layer on the glass substrate and the black matrix layer; and executing an exposure and development process for the first color resist layer to simultaneously form the first color resist units in the corresponding blank spaces of the black matrix layer and form the first spacer portions on the black matrix layer.

In one embodiment of the present invention, the area of the first spacer portion is greater than that of the second spacer portion, and the area of the second spacer portion is greater than that of the third spacer portion.

In one embodiment of the present invention, the manufacturing method forms the first, second and third color resist units by transfer printing, and thus uses the same color resist material of each type of color resist units to form the spacers on the black matrix layer by multi-coating in the same process of forming one type of the first, second and third color resist units.

To further achieve the above object, the present invention provides a color filter structure, wherein the color filter structure comprises:

a glass substrate;

a black matrix layer formed on the glass substrate and having a plurality of blank spaces;

a color pixel layer formed on the glass substrate and including a plurality of first color resist units, second color resist units and third color resist units, wherein the first, second and third color resist units are formed in the corresponding blank spaces of the black matrix layer, respectively;

a plurality of spacers formed on the black matrix layer, wherein each of the spacers is constructed by at least one identical color resist material of the first, second and third color resist units, and wherein the height of the spacer is greater than that of the first, second or third color resist units; and

a transparent conductive layer covered on the black matrix layer, the color pixel layer and the spacers.

In one embodiment of the present invention, the color filter structure further comprises a transparent planarized photo-resist layer covered on the transparent conductive layer.

In one embodiment of the present invention, each of the spacers comprises a first spacer portion, a second spacer portion and a third spacer portion, while the first, second and third spacer portions are formed by the same color resist material of the first, second and third color resist units, respectively.

In one embodiment of the present invention, the first spacer portion, the second spacer portion and the third spacer portion are stacked from bottom to top, wherein the area of the first spacer portion is greater than that of the second spacer portion, and the area of the second spacer portion is greater than that of the third spacer portion.

To further achieve the above object, the present invention provides a manufacturing method of a color filter structure, which comprises the following steps of:

preparing a glass substrate and forming a black matrix layer on the glass substrate, wherein the black matrix layer defines a plurality of blank spaces;

forming a plurality of first color resist units, second color resist units and third color resist units in the corresponding blank spaces of the black matrix layer, respectively, wherein the first, second and third color resist units commonly define a color pixel layer;

using the same color resist material of at least one type of color resist units to form a plurality of spacers on the black matrix layer in the same process of forming the at least one type of the first, second and third color resist units; and

forming a transparent conductive layer covered on the black matrix layer, the color pixel layer and the spacers.

In one embodiment of the present invention, after the step of forming the transparent conductive layer, further comprising: forming a transparent planarized photo-resist layer covered on the transparent conductive layer.

In one embodiment of the present invention, in the step of using the same color resist material of the at least one type of color resist units to form the spacers on the black matrix layer in the same process of forming the at least one type of the first, second and third color resist units, comprising:

using the same color resist material of the first color resist units to form the first spacer portions on the black matrix layer in the same process of forming the first color resist units;

using the same color resist material of the second color resist units to form the second spacer portions on the first spacer portions in the same process of forming the second color resist units; and

using the same color resist material of the third color resist units to form the third spacer portions on the second spacer portions in the same process of forming the third color resist units, wherein each of the first spacer portions, the second spacer portions and the third spacer portions are stacked to form a spacer.

In one embodiment of the present invention, in the step of forming the first color resist units in the corresponding blank spaces of the black matrix layer and using the same color resist material of the first color resist units to form the first spacer portions on the black matrix layer in the same process of forming the first color resist units, comprising: forming a first color resist layer on the glass substrate and the black matrix layer, executing an exposure and development process for the first color resist layer to simultaneously form the first color resist units in the corresponding blank spaces of the black matrix layer and form the first spacer portions on the black matrix layer.

In one embodiment of the present invention, the area of the first spacer portion is greater than that of the second spacer portion, and the area of the second spacer portion is greater than that of the third spacer portion.

In one embodiment of the present invention, the manufacturing method forms the first, second and third color resist units by transfer printing, and thus using the same color resist material of each type of color resist units to form the spacers on the black matrix layer by multi-coating in the same process of forming each type of the first, second and third color resist units.

In comparison with the traditional technology which needs a separate exposure and development process to form the spacers, the manufacturing method of the color filter structure of the present invention can simultaneously form the spacers by using the same color resist when forming the color pixel layer, so that the step of forming a photo-resist layer and locally exposing the photo-resist layer to form the spacers can be omitted. Thus, the manufacture process of the spacers is relatively simple, and the manufacture cost thereof is relatively low, so as to save the manufacture cost of the color filter structure.

### DESCRIPTION OF THE DRAWINGS

FIGS. 1A to 1G are schematic views of a manufacturing method of a traditional color filter structure;

FIGS. 2A to 2F are schematic views of a manufacturing method of a color filter structure according to a first embodiment of the present invention;

FIG. 3 is a flowchart of the manufacturing method of the color filter structure according to the first embodiment of the present invention;

FIG. 4 is a partially enlarged view of a color filter structure according to a second embodiment of the present invention; and

FIG. 5 is a partially enlarged view of a color filter structure according to a third embodiment of the present invention.

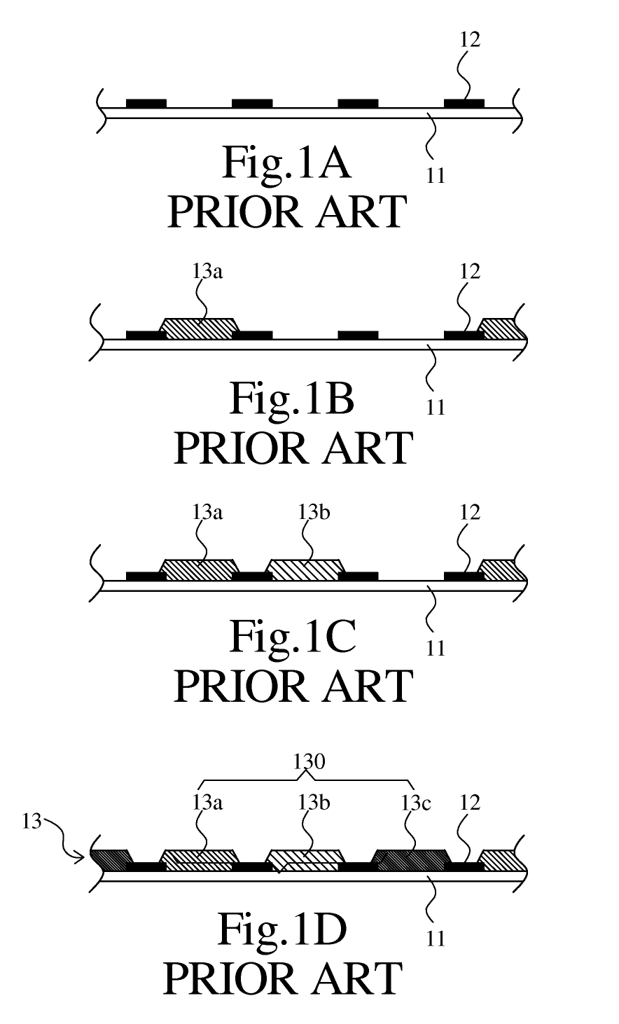

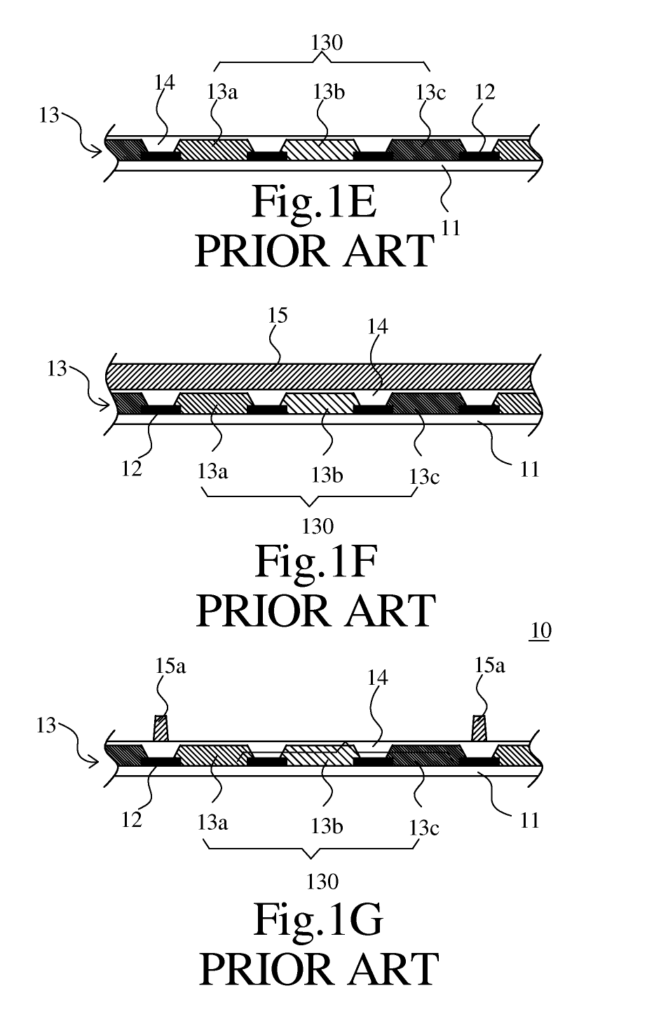

### DETAILED DESCRIPTION OF THE PREFERRED EMBODIMENTS

The structure and the technical means adopted by the present invention to achieve the above and other objects can be best understood by referring to the following detailed description of the preferred embodiments and the accompanying drawings.

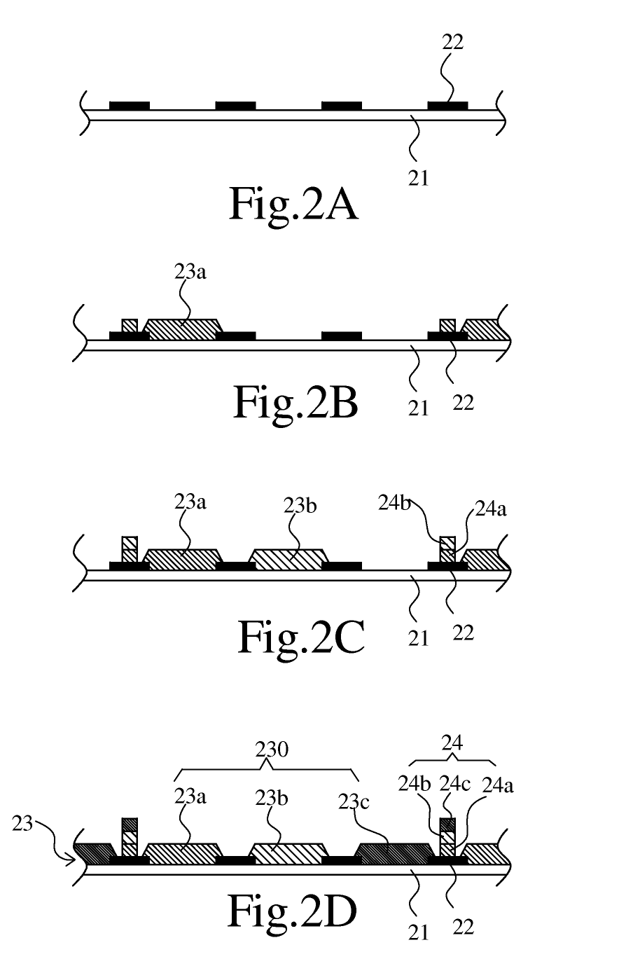

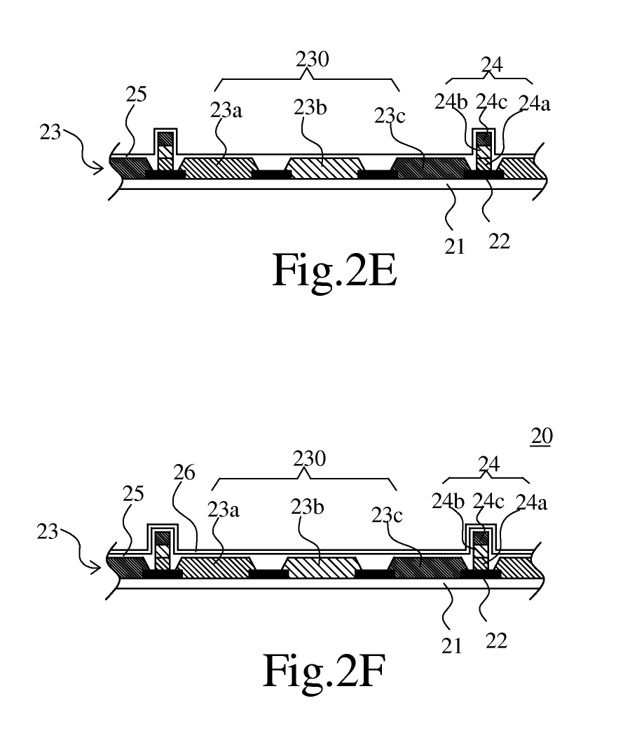

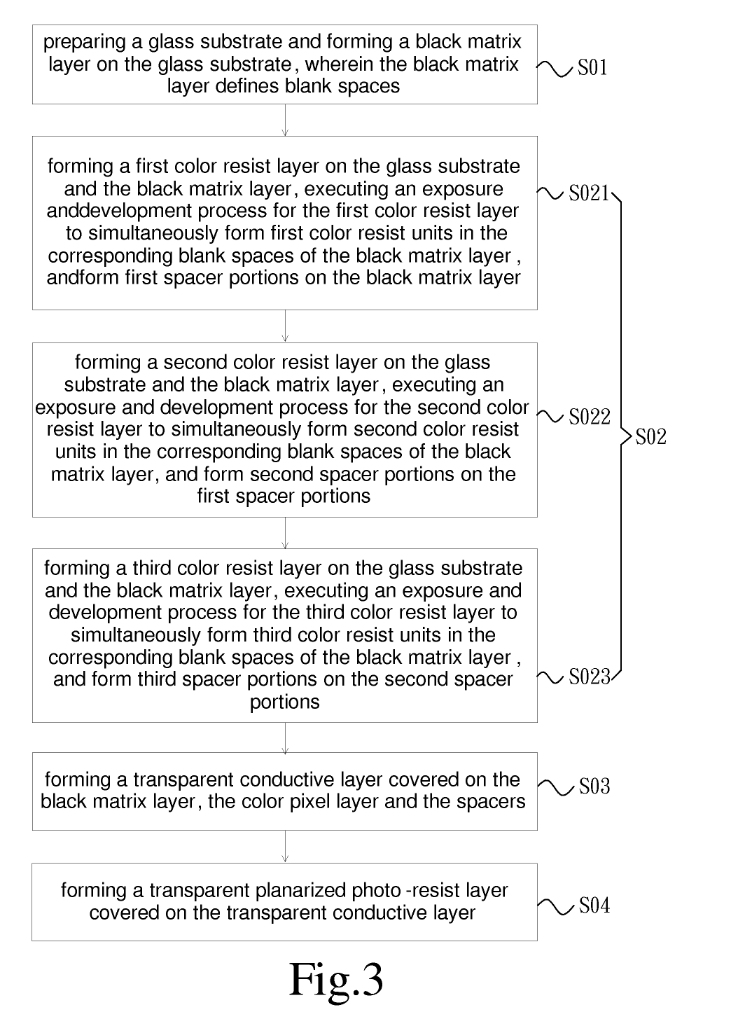

Referring now to FIGS. 2A to 2F and 3, FIGS. 2A to 2F illustrate schematic views of a manufacturing method of a color filter structure 20 according to a first embodiment of the present invention; and FIG. 3 illustrates a flowchart of the manufacturing method of the color filter structure according to the first embodiment of the present invention.

Firstly, as shown in FIG. 2A, in a step (S01), preparing a glass substrate 21 and forming a black matrix layer 22 on the glass substrate 21, wherein the black matrix layer 22 defines a plurality of blank spaces;

Then, as shown in FIGS. 2B to 2D, in a step (S02), forming a plurality of first color resist units 23a, second color resist units 23b and third color resist units 23c in the corresponding blank spaces of the black matrix layer 22 on the glass substrate 21, respectively, wherein the first, second and third color resist units 23a, 23b, 23c commonly define a color pixel layer 23. In the same process of forming the color pixel layer 23 (i.e. forming at least one type of the first, second and third color resist units 23a, 23b, 23c), using the same color resist material of the at least one type of color resist units to form a plurality of spacers 24 on the black matrix layer 22.

The step (S02) according to the first embodiment of the present invention can be divided into three steps, as follows:

(1) In a step (S021): forming a first color resist layer (not-shown) on the glass substrate 21 and the black matrix layer 22, executing an exposure and development process for the first color resist layer to simultaneously form the first color resist units 23a in the corresponding blank spaces of the black matrix layer 22, and form the first spacer portions 24a on the black matrix layer 22 (as shown in FIG. 2B). In other words, in the same process of forming the first color resist units 23a, using the same color resist material of the first color resist units 23a to form first spacer portions 24a on the black matrix layer 22;

(2) In a step (S022): forming a second color resist layer (not-shown) on the glass substrate 21 and the black matrix layer 22, executing an exposure and development process for the second color resist layer to simultaneously form the second color resist units 23b in the corresponding blank spaces of the black matrix layer 22, and form the second spacer portions 24b on the first spacer portions 24a (as shown in FIG. 2C). In other words, in the same process of forming the second color resist units 23b, using the same color resist material of the second color resist units 23b to form second spacer portions 24b on the first spacer portions 24a;

(3) In a step (S023): then, forming a third color resist layer (not-shown) on the glass substrate 21 and the black matrix layer 22, executing an exposure and development process for the third color resist layer to simultaneously form the third color resist units 23c in the corresponding blank spaces of the black matrix layer 22, and form the third spacer portions 24c on the second spacer portions 24b (as shown in FIG. 2D). In other words, in the same process of forming the third color resist units 23c, using the same color resist material of the third color resist units 23c to form third spacer portions 24c on the second spacer portions 24b;

Thus, one of the first color resist units 23a, one of the second color resist units 23b and one of the third color resist units 23c adjacent to each other are commonly define a set of pixel unit 230, while all of the pixel units 230 commonly define a color pixel layer 23. The first color resist units 23a, the second color resist units 23b and the third color resist units 23c are disposed at the same level of horizontal height, and the horizontal height thereof is slight higher than that of the black matrix layer 22. Furthermore, the first spacer portions 24a, the second spacer portions 24b and the third spacer portions 24c are stacked on the surface of the black matrix layer 22 in turn, wherein the height of the first, second and third spacer portions 24a, 24b, 24c increase in turn. Thus, one of the first spacer portions 24a, one of the second spacer portions 24b and one of the third spacer portions 24c are stacked in turn to form one of the spacers 24.

Finally, as shown in FIG. 2E, in a step (S03), forming a transparent conductive layer 25 covered on the black matrix layer 22, the color pixel layer 23 and the spacers 24.

Furthermore, as shown in FIG. 2E, in a step (SO4), further forming a transparent planarized photo-resist layer 26 covered on the transparent conductive layer 25.

In the first embodiment of the present invention, in the step of forming the first color resist units 23a, the second color resist units 23b and the third color resist units 23c in the corresponding blank spaces of the black matrix layer 22 on the glass substrate 21. using the same color resist material of at least one type of the first, second and third color resist units 23a, 23b, 23c to form the spacers 24 on the black matrix layer 22 in the same process of forming at least one type of the first, second and third color resist units 23a, 23b, 23c. That is, in at least one step of these three steps (S021) to (S023), at least one spacer portions 24a, 24b or 24c are formed for defining the spacers 24. Alternatively, in other words, each of the spacers 24 is formed by at least one of the spacer portions 24a, 24b or 24c, wherein each of the spacers 24 has a height greater than the height of each of the first, second and third color resist units 23a, 23b and 23c. Thus, it can satisfy the basic need of the spacers 24 of the color filter structure 20 of the present invention.

The method of forming the first, second and third color resist units 23a, 23b and 23c preferably includes the steps of: firstly forming each of the color resist layer on the glass substrate 21 and the black matrix layer 22; then using a photo-mask to generate openings corresponding to blank spaces of the black matrix layer 22 and generate openings corresponding to the predetermined position of the spacers 24; executing an exposure and development process to simultaneously form each of the color resist units 23a, 23b and 23c in the corresponding blank spaces of the black matrix layer 22 and form each of the spacer portions 24a, 24b and 24c on the black matrix layer 22. However, in the present invention, the method of forming the color resist units 23a, 23b and 23c and the spacer portions 24a, 24b and 24c is not limited thereto. As described above, the present invention can use lithography, dry film, transfer printing or inkjet printing to form each of the color resist units 23a, 23b and 23c in the corresponding blank spaces of the black matrix layer 22 and form each of the spacer portions 24a, 24b and 24c on the black matrix layer 22, without limitation.

Moreover, in the present invention, the transparent conductive layer 25 or the transparent planarized photo-resist layer 26 can be formed by sputtering, spin coating or evaporation, but the present invention is not limited thereto.

As described above, a user can select a suitable method according to actual needs to carry out a purpose of simultaneously forming the spacers 24 on the black matrix layer 22 by using the same color resist material of at least one type of the color resist units 23a, 23b and 23c in the same process of forming at least one type of the first, second and third color resist units 23a, 23b and 23c when forming the color pixel layer 23. Thus, the present invention provides a manufacturing method of a color filter structure, which comprises the following steps of:

(1) preparing a glass substrate 21 and forming a black matrix layer 22 on the glass substrate 21, wherein the black matrix layer defines a plurality of blank spaces;

(2) forming a plurality of first color resist units 23a, second color resist units 23b and third color resist units 23c in the corresponding blank spaces of the black matrix layer 22, respectively, wherein the first, second and third color resist units 23a, 23b, 23c commonly define a color pixel layer 23;

(3) using the same color resist material of the at least one type of color resist units 23a, 23b, 23c to form a plurality of spacers 24 on the black matrix layer 22 in the same process of forming at least one type of the first, second and third color resist units 23a, 23b, 23c; and

(4) forming a transparent conductive layer 25 covered on the black matrix layer 22, the color pixel layer 23 and the spacers 24.

(5) further forming a transparent planarized photo-resist layer 26 covered on the transparent conductive layer 25.

According to the foregoing steps, the color filter structure 20 of the first embodiment of the present invention can be prepared. As shown in FIG. 2F, the color filter structure 20 of the first embodiment of the present invention comprises a glass substrate 21, a black matrix layer 22, a color pixel layer 23, a plurality of spacers 24 and a transparent conductive layer 25. The glass substrate 21 is used as a base material. The black matrix layer 22 is formed on the glass substrate 21 and the black matrix layer 22 has a plurality of blank spaces (unlabeled). The color pixel layer 23 is formed on the glass substrate 21 and includes a plurality of first color resist units 23a, second color resist units 23b and third color resist units 23c, wherein the first, second and third color resist units 23a, 23b, 23c are formed in the corresponding blank spaces of the black matrix layer 22, respectively. The plurality of spacers 24 are formed on the black matrix layer 22, and each of the spacers 24 is constructed by at least one identical color resist material of the first, second and third color resist units 23a, 23b, 23c, wherein the height of the spacer 24 is greater than that of the first, second or third color resist units 23a, 23b, 23c. The transparent conductive layer 25 is covered on the black matrix layer 22, the color pixel layer 23 and the spacers 24. The transparent planarized photo-resist layer 26 is covered on the transparent conductive layer 25.

Furthermore, in the present invention, the color resist units 23a, 23b, 23c are preferably red (R) color resist, green (G) color resist and blue (B) color resist, each of which is formed in the corresponding blank spaces of the black matrix layer 22. Correspondingly, the first spacer portions 24a are preferably made of the color resist material of the first color resist units 23a; the second spacer portions 24b are preferably made of the color resist material of the second color resist units 23b; and the third spacer portions 24c are preferably made of the color resist material of the third color resist units 23c.

The spacers 24 of the color filter structure 20 of the present invention has a height greater than that of the first, second or third color resist units 23a, 23b, 23c. When the color filter structure 20 is further installed with a TFT substrate (not-shown), the spacers 24 keeps a gap distance between the color filter structure 20 and the TFT substrate for evenly filling the liquid crystal material into the gap. Furthermore, when the color filter structure 20 is installed with the TFT substrate, the transparent planarized photo-resist layer 26 can prevent the surface of the transparent conductive layer 25 from being directly in contact with the TFT substrate to cause short circuit problems. However, in another possible embodiment of the present invention, if the TFT substrate has had another design to prevent the short circuit of the surface thereof, the color filter structure and the manufacturing method thereof according to the present invention can omit the transparent planarized photo-resist layer 26.

In the traditional manufacturing method of the color filter structure, the spacers are formed by the final step of exposure and development, and thus needs several processes of forming a photo-resist layer, fabricating a photo-mask and executing the exposure and development, so that the traditional manufacturing method of the color filter structure is complicated and the manufacture cost thereof is high. In contrast, in the present invention, when forming the color pixel layer 23, each of the spacers 24 is formed on the black matrix layer 22 by at least one identical color resist material of the first, second and third color resist units 23a, 23b, 23c in the same process of forming at least one type of the first, second and third color resist units 23a, 23b, 23c. In comparison with the traditional technology, the present invention can omit a step of forming a photo-resist layer and locally exposing the photo-resist layer to form spacers. Furthermore, in comparison with the complicated steps of forming the photo-resist layer and executing the exposure and development for the traditional spacers and the manufacture cost thereof, even though the present invention needs to increase the transparent planarized photo-resist layer 26 to prevent the transparent conductive layer 25 from the short-circuit problems during installation, the installation of the transparent planarized photo-resist layer 26 is still relatively simple and the manufacture cost thereof is relatively low, so as to save the manufacture cost of the color filter structure 20.

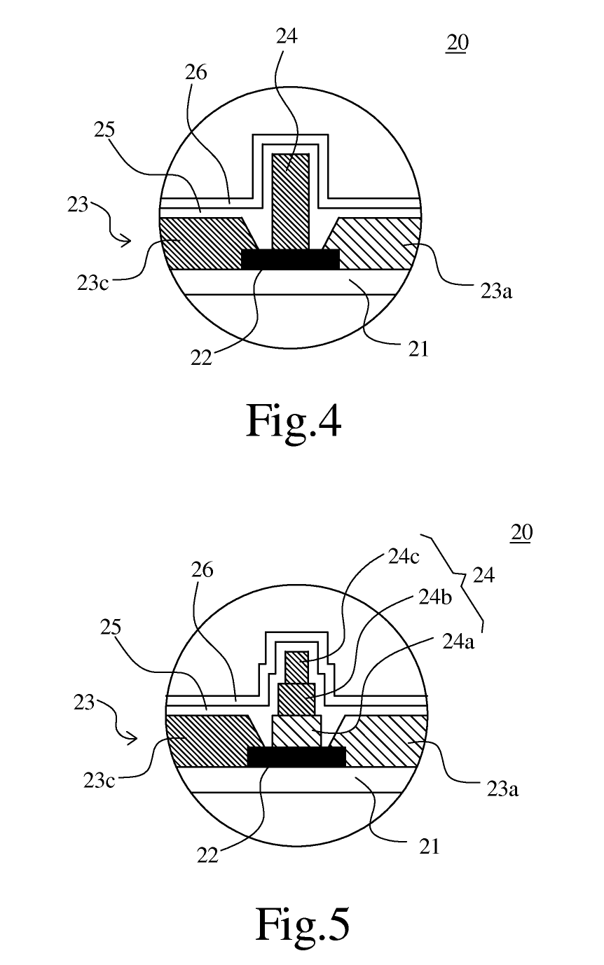

Referring now to FIG. 4, a color filter structure according to a second embodiment of the present invention is illustrated. As shown in FIG. 4, the color filter structure 20 of the second embodiment of the present invention is similar to the color filter structure 20 of the first embodiment of the present invention, so that the second embodiment uses similar terms or numerals of the first embodiment. But, the difference of the second embodiment is that each of the spacers 24 of the second embodiment only made of a single color resist material (spacer portion). In the same process of forming the first color resist unit 23a, the second color resist unit 23b and the third color resist unit 23a in the blank spaces of the black matrix layer 22 on the glass substrate 21, one of the color resist material (the spacer portions 24a, 24b or 24c) can be used to additional form the spacers 24. Of course, the single spacer portions 24a, 24b or 24c must has a higher thickness, and the height thereof is greater than that of the first, second or third color resist units 23a, 23b, 23c for generating a gap distance between the color filter structure 20 and the TFT substrate. For example, the manufacturing method forms the first, second and third color resist units 23a, 23b, 23c by transfer printing, and thus uses the same color resist material of each type of color resist units to form the spacers 24 on the black matrix layer 22 in the same process of forming one type of the first, second and third color resist units 23a, 23b, 23c. However, in the present invention, the number of the spacer portions 24a, 24b or 24c, the thickness or the stack order thereof is not limited thereto, and can be flexibly adjusted according to actual needs in use.

Referring now to FIG. 5, a color filter structure according to a third embodiment of the present invention is illustrated. As shown in FIG. 5, the color filter structure 20 of the third embodiment of the present invention is similar to the color filter structure 20 of the first embodiment of the present invention, so that the third embodiment uses similar terms or numerals of the first embodiment. But, the difference of the third embodiment is that the first spacer portion 24a, the second spacer portion 24b and the third spacer portion 24c are stacked from bottom to top, wherein the area of the first spacer portion 24a is greater than that of the second spacer portion 24b, and the area of the second spacer portion 24b is greater than that of the third spacer portion 24c. That is, no matter what order the spacer portions 24a, 24b and 24c is, a lower layer of the spacer portions 24a, 24b and 24c has an area slightly greater than that of another adjacent higher layer of spacer portions 24a, 24b and 24c. Alternatively, a lower area of the spacer 24 is greater than an upper area of the spacer 24. Thus, the spacer 24 can be stably mounted on the black matrix layer 22.

As described above, in comparison with the traditional manufacturing method of the color filter structure that finally needs an exposure and development process to form the spacers and is thus relatively complicated and has relatively high manufacture cost, the present invention can simultaneously form the spacers 24 when forming the color pixel layer 23. In comparison with the traditional technology, the present invention can omit a step of forming a photo-resist layer and locally exposing the photo-resist layer to form spacers. Thus, the color filter structure 20 and the manufacturing method thereof according to the present invention is relatively simple and the manufacture cost thereof is relatively low, so as to save the manufacture cost of the color filter structure 20.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A manufacturing method of a color filter structure, comprising steps of:
preparing a glass substrate and forming a black matrix layer on the glass substrate, wherein the black matrix layer defines a plurality of blank spaces;
forming a plurality of first color resist units, second color resist units and third color resist units in the corresponding blank spaces of the black matrix layer, respectively, wherein the first, second and third color resist units commonly define a color pixel layer;
using the same color resist material of the first color resist units to form first spacer portions on the black matrix layer in the same process of forming the first color resist units;
using the same color resist material of the second color resist units to form second spacer portions on the first spacer portions in the same process of forming the second color resist units;
using the same color resist material of the third color resist units to form third spacer portions on the second spacer portions in the same process of forming the third color resist units, wherein each of the first spacer portions, the second spacer portions and the third spacer portions are stacked to form a spacer;
forming a transparent conductive layer covered on the black matrix layer, the color pixel layer and the spacers; and
forming a transparent planarized photo-resist layer covered on the transparent conductive layer.

2. The manufacturing method of the color filter structure according to claim 1, wherein in the step of forming the first color resist units in the corresponding blank spaces of the black matrix layer and using the same color resist material of the first color resist units to form the first spacer portions on the black matrix layer in the same process of forming the first color resist units, comprising:
forming a first color resist layer on the glass substrate and the black matrix layer; and executing an exposure and development process for the first color resist layer to simultaneously form the first color resist units in the corresponding blank spaces of the black matrix layer and form the first spacer portions on the black matrix layer.

3. The manufacturing method of the color filter structure according to claim 1, wherein the area of the first spacer portion is greater than that of the second spacer portion, and the area of the second spacer portion is greater than that of the third spacer portion.

4. The manufacturing method of the color filter structure according to claim 2, wherein the area of the first spacer portion is greater than that of the second spacer portion, and the area of the second spacer portion is greater than that of the third spacer portion.

5. The manufacturing method of the color filter structure according to claim 1, wherein the manufacturing method forms the first, second and third color resist units by transfer printing, and uses the same color resist material of each type of color resist units to form the spacers on the black matrix layer in the same process of forming one type of the first, second and third color resist units.

6. A color filter structure, wherein the color filter structure comprises:
a glass substrate;
a black matrix layer formed on the glass substrate and having a plurality of blank spaces;
a color pixel layer formed on the glass substrate and including a plurality of first color resist units, second color resist units and third color resist units, wherein the first, second and third color resist units are formed in the corresponding blank spaces of the black matrix layer, respectively;
a plurality of spacers formed on the black matrix layer, wherein each of the spacers is constructed by at least one identical color resist material of the first, second and third color resist units, and wherein the height of the spacer is greater than that of the first, second or third color resist units; and
a transparent conductive layer covered on the black matrix layer, the color pixel layer and the spacers.

7. The color filter structure according to claim 6, wherein the color filter structure further comprises a transparent planarized photo-resist layer covered on the transparent conductive layer.

8. The color filter structure according to claim 6, wherein each of the spacers comprises a first spacer portion, a second spacer portion and a third spacer portion, while the first, second and third spacer portions are formed by the same color resist material of the first, second and third color resist units, respectively.

9. The color filter structure according to claim 8, wherein the first spacer portion, the second spacer portion and the third spacer portion are stacked from bottom to top, wherein the area of the first spacer portion is greater than that of the second spacer portion, and the area of the second spacer portion is greater than that of the third spacer portion.

10. A manufacturing method of a color filter structure, comprising steps of:
preparing a glass substrate and forming a black matrix layer on the glass substrate, wherein the black matrix layer defines a plurality of blank spaces;
forming a plurality of first color resist units, second color resist units and third color resist units in the corresponding blank spaces of the black matrix layer, respectively, wherein the first, second and third color resist units commonly define a color pixel layer;
using the same color resist material of at least one type of color resist units to form a plurality of spacers on the black matrix layer in the same process of forming the at least one type of the first, second and third color resist units; and
forming a transparent conductive layer covered on the black matrix layer, the color pixel layer and the spacers.

11. The manufacturing method of the color filter structure according to claim 10, wherein after the step of forming the transparent conductive layer, further comprising: forming a transparent planarized photo-resist layer covered on the transparent conductive layer.

12. The manufacturing method of the color filter structure according to claim 10, wherein in the step of using the same color resist material of the at least one type of color resist units to form the spacers on the black matrix layer in the same process of forming the at least one type of the first, second and third color resist units, comprising:
using the same color resist material of the first color resist units to form the first spacer portions on the black matrix layer in the same process of forming the first color resist units;
using the same color resist material of the second color resist units to form the second spacer portions on the first spacer portions in the same process of forming the second color resist units; and
using the same color resist material of the third color resist units to form the third spacer portions on the second spacer portions in the same process of forming the third color resist units, wherein each of the first spacer portions, the second spacer portions and the third spacer portions are stacked to form a spacer.

13. The manufacturing method of the color filter structure according to claim 12, wherein in the step of forming the first color resist units in the corresponding blank spaces of the black matrix layer and using the same color resist material of the first color resist units to form the first spacer portions on the black matrix layer in the same process of forming the first color resist units, comprising:
forming a first color resist layer on the glass substrate and the black matrix layer; and executing an exposure and development process for the first color resist layer to simultaneously form the first color resist units in the corresponding blank spaces of the black matrix layer and form the first spacer portions on the black matrix layer.

14. The manufacturing method of the color filter structure according to claim 12, wherein the area of the first spacer portion is greater than that of the second spacer portion, and the area of the second spacer portion is greater than that of the third spacer portion.

15. The manufacturing method of the color filter structure according to claim 13, wherein the area of the first spacer portion is greater than that of the second spacer portion, and the area of the second spacer portion is greater than that of the third spacer portion.

16. The manufacturing method of the color filter structure according to claim 10, wherein the manufacturing method forms the first, second and third color resist units by transfer printing, and uses the same color resist material of each type of color resist units to form the spacers on the black matrix layer in the same process of forming one type of the first, second and third color resist units.
